(19) United States
(12) Patent Application Publication
(10) Pub. No.: US 2026/0314245 A1
(43) Pub. Date: Oct. 8, 2026

(54) TOUCH DISPLAY PANEL, MANUFACTURING METHOD THEREOF, AND DISPLAY DEVICE

(71) Applicant: BOE TECHNOLOGY GROUP CO., LTD., Beijing (CN)

(72) Inventors: Yuanyuan Li, Beijing (CN); Shiming Shi, Beijing (CN); Song Zhang, Beijing (CN); Mingche Hsieh, Beijing (CN); Wenxiu Zhu, Beijing (CN)

(73) Assignee: BOE TECHNOLOGY GROUP CO., LTD., Beijing (CN)

(21) Appl. No.: 19/481,610

(22) PCT Filed: Jan. 14, 2025
(86) PCT No.: PCT/CN2025/072225

§ 371 Date: Nov. 5, 2025

(30) Foreign Application Priority Data
Feb. 28, 2024 (CN) 202410225438.3

(51) Int. Cl. H10K 59/80; H10K 59/12; H10K 59/40

(52) U.S. Cl. CPC H10K 59/8792; H10K 59/1201; H10K 59/40

(57) ABSTRACT

A touch display panel, a manufacturing method thereof, and a display device are provided. The touch display panel includes a plurality of sharing sub-pixels and a plurality of anti-peeping sub-pixels, and each anti-peeping sub-pixel includes at least two anti-peeping pixel apertures. The touch display panel further includes: a first light-shielding layer, a touch layer, and a second light-shielding layer. The first light-shielding layer defines a plurality of first apertures, and an orthographic projection of each first aperture on a base substrate at least partially overlaps with an orthographic projection of a corresponding anti-peeping pixel aperture on the base substrate. The touch layer is reused as the second light-shielding layer. An orthographic projection of the second light-shielding layer on the base substrate defines a plurality of second apertures, each second aperture at least partially overlaps with an orthographic projection of a corresponding anti-peeping pixel aperture on the base substrate.

### CROSS-REFERENCE TO RELATED APPLICATION

The present application claims priority to Chinese Patent Application No. 202410225438.3 filed in China on Feb. 28, 2024, the entire contents of which are incorporated herein by reference.

### TECHNICAL FIELD

The present disclosure relates to the technical field of touch display, and in particular to a touch display panel, a manufacturing method thereof, and a display device.

### BACKGROUND

In real-world use, display products often need to switch between two modes: anti-peeping mode for private situations, and screen sharing mode when for group moments. This requires the display screen to have the capability to toggle between the anti-peeping mode and the screen sharing mode any moment. For example, when using a mobile phone to view information in a public place, present a payment code or enter a password, the mobile phone display screen can be switched to the anti-peeping mode. In other occasions, the mobile phone display screen can be switched to the sharing mode. In addition, for example, when using a vehicle-mounted application display screen, the display screen can be switched to the anti-peeping mode when the co-pilot watches entertainment information, to the sharing mode when in some other situations.

In the related state of the art, display products require complex designs, excessive thickness, and high manufacturing costs when enabling the switching between the anti-peeping mode and the screen sharing mode as described above.

### SUMMARY

An objective of the present disclosure is to provide a touch display panel, a manufacturing method thereof, and a display device.

To achieve the above objective, the present disclosure provides the following technical solutions.

A first aspect of the present disclosure provides a touch display panel, including: a base substrate and a plurality of sub-pixels disposed on the base substrate. The plurality of sub-pixels include a plurality of sharing sub-pixels and a plurality of anti-peeping sub-pixels, and each anti-peeping sub-pixel includes at least two anti-peeping pixel apertures. The touch display panel further includes:
a first light-shielding layer, where the first light-shielding layer defines a plurality of first apertures; an orthographic projection of each first aperture on the base substrate at least partially overlaps with an orthographic projection of a corresponding anti-peeping pixel aperture on the base substrate; and at least part of an orthographic projection of the first light-shielding layer on the base substrate is located at a periphery of an orthographic projection of at least part of the anti-peeping pixel apertures on the base substrate;
a touch layer, where the touch layer is located on a side of the first light-shielding layer facing away from the base substrate;
where the touch layer is reused as a second light-shielding layer; an orthographic projection of the second light-shielding layer on the base substrate defines a plurality of second apertures; each second aperture at least partially overlaps with an orthographic projection of a corresponding anti-peeping pixel aperture on the base substrate; and at least part of the orthographic projection of the second light-shielding layer on the base substrate is located at a periphery of the orthographic projection of at least part of the anti-peeping pixel apertures on the base substrate.

Optionally, an orthographic projection of a boundary of each anti-peeping pixel aperture on the base substrate is surrounded by an orthographic projection of a boundary of a corresponding first aperture on the base substrate; or at least part of the orthographic projection of the boundary of each anti-peeping pixel aperture on the base substrate is located inside the orthographic projection of the first light-shielding layer on the base substrate;
and/or,
an orthographic projection of a boundary of each anti-peeping pixel aperture on the base substrate is surrounded by a boundary of a corresponding second aperture; or at least part of the orthographic projection of the boundary of each anti-peeping pixel aperture on the base substrate is located inside the orthographic projection of the second light-shielding layer on the base substrate.

Optionally, the second apertures corresponding to the anti-peeping pixel apertures for the same anti-peeping sub-pixel together serve as one aperture unit; the touch layer includes a plurality of light-shielding parts, with an orthographic projection of each light-shielding part on the base substrate defining a corresponding aperture unit; and the plurality of light-shielding parts are either independent of each other, or at least two of the light-shielding parts are coupled.

Optionally, each light-shielding part includes at least two sub-portions; an orthographic projection of each sub-portion on the base substrate defines a corresponding second aperture; the sub-portions belonging to a same light-shielding part are independent of each other, or at least two of the sub-portions belonging to the same light-shielding part are coupled.

Optionally, the touch layer includes independent touch electrodes and dummy electrodes, and at least one of the touch electrodes and the dummy electrodes includes the light-shielding parts.

Optionally, each touch electrode includes an effective electrode portion; the light-shielding part included in each touch electrode is coupled to the effective electrode portion; and/or the light-shielding part included in each dummy electrode is independent of the effective electrode portion.

Optionally, an orthographic projection of the light-shielding part included in each touch electrode on the base substrate is at least partially surrounded by an orthographic projection of the effective electrode portion on the base substrate; and/or an orthographic projection of the light-shielding part included in each dummy electrode on the base substrate is at least partially surrounded by the orthographic projection of the effective electrode portion on the base substrate.

Optionally, each dummy electrode includes an ineffective electrode portion; the light-shielding part included in each dummy electrode is coupled to at least part of the ineffective electrode portion; or the light-shielding part included in each dummy electrode is independent of the ineffective electrode portion.

Optionally, an orthographic projection of each light-shielding part on the base substrate is formed into a grid structure, with each grid in the grid structure correspondingly defining one second aperture.

Optionally, each touch electrode includes an effective electrode portion, and at least part of the effective electrode portion is reused as the light-shielding part.

Optionally, the touch layer includes at least one touch electrode layer, and the touch electrode layer is reused as the second light-shielding layer.

Optionally, the touch layer includes a first touch electrode layer and a second touch electrode layer that are sequentially stacked along a direction away from the base substrate; the touch display panel includes two stacked second light-shielding layers, the first touch electrode layer being reused as one second light-shielding layer, and the second touch electrode layer being reused as the other second light-shielding layer.

Optionally, the touch layer includes a first touch electrode layer and a second touch electrode layer that are sequentially stacked along a direction away from the base substrate; the first touch electrode layer is reused as a part of the second light-shielding layer, and the second touch electrode layer is reused as another part of the second light-shielding layer.

Optionally, at least one second aperture is jointly defined by an orthographic projection of the first touch electrode layer on the base substrate and an orthographic projection of the second touch electrode layer on the base substrate.

Optionally, the touch display panel further includes: a plurality of lens structures, where the plurality of lens structures are located on a side of the touch layer facing away from the base substrate, and an orthographic projection of each lens structure on the base substrate covers an orthographic projection of a corresponding anti-peeping pixel aperture on the base substrate.

Optionally, the plurality of sharing sub-pixels are grouped into a plurality of sharing pixel units, and each sharing pixel unit includes at least two sharing sub-pixels; the plurality of anti-peeping sub-pixels are grouped into a plurality of anti-peeping pixel units, and each anti-peeping pixel unit includes at least two anti-peeping sub-pixels;
where the plurality of sharing pixel units are grouped into a plurality of rows of sharing pixel unit rows, the plurality of anti-peeping pixel units are grouped into a plurality of rows of anti-peeping pixel unit rows, and the sharing pixel unit rows and the anti-peeping pixel unit rows are alternately arranged.

Based on the technical solution of the above touch display panel, a second aspect of the present disclosure provides a display device including the above touch display panel.

Based on the technical solution of the above touch display panel, a third aspect of the present disclosure provides a method of manufacturing a touch display panel, including:
forming a plurality of sub-pixels on a base substrate, where the plurality of sub-pixels include a plurality of sharing sub-pixels and a plurality of anti-peeping sub-pixels, and each anti-peeping sub-pixel includes at least two anti-peeping pixel apertures;
forming a first light-shielding layer on a side of the plurality of sub-pixels facing away from the base substrate, where the first light-shielding layer defines a plurality of first apertures, an orthographic projection of each first aperture on the base substrate at least partially overlaps with an orthographic projection of a corresponding anti-peeping pixel aperture on the base substrate, and at least part of an orthographic projection of the first light-shielding layer on the base substrate is located at a periphery of an orthographic projection of at least part of the anti-peeping pixel apertures on the base substrate; and
forming a touch layer on a side of the first light-shielding layer facing away from the base substrate, where the touch layer is reused as a second light-shielding layer, an orthographic projection of the second light-shielding layer on the base substrate defines a plurality of second apertures, each second aperture at least partially overlaps with an orthographic projection of a corresponding anti-peeping pixel aperture on the base substrate, and at least part of the orthographic projection of the second light-shielding layer on the base substrate is located at a periphery of the orthographic projection of at least part of the anti-peeping pixel apertures on the base substrate.

### BRIEF DESCRIPTION OF THE DRAWINGS

The drawings included here are used to facilitate a better understanding of the present disclosure and constitute a part of the present disclosure. The illustrative embodiments of the present disclosure and their descriptions are intended to explain this disclosure rather than to unduly limit it. In the drawings:

FIG. 1 is a first cross-sectional schematic view of a touch display panel provided by an embodiment of the present disclosure;

FIG. 2 is a second cross-sectional schematic view of a touch display panel provided by an embodiment of the present disclosure;

FIG. 3 is a third cross-sectional schematic view of a touch display panel provided by an embodiment of the present disclosure;

FIG. 4 is a fourth cross-sectional schematic view of a touch display panel provided by an embodiment of the present disclosure;

FIG. 5 is a first plan view of a touch display panel provided by an embodiment of the present disclosure;

FIG. 6 is an enlarged schematic view of part A1 in FIG. 5;

FIG. 7 is a cross-sectional schematic view along the direction B1B2 in FIG. 6;

FIG. 8 is a second plan view of a touch display panel provided by an embodiment of the present disclosure;

FIG. 9 is an enlarged schematic view of part A2 in FIG. 8;

FIG. 10 is an enlarged schematic view of part A3 in FIG. 8;

FIG. 11 is a third plan view of a touch display panel provided by an embodiment of the present disclosure;

FIG. 12 is an enlarged schematic view of anti-peeping sub-pixels and sharing subpixels in FIG. 11;

FIG. 13 is a cross-sectional schematic view along the direction C1C2 in FIG. 12.

### DETAILED DESCRIPTION

To further describe the touch display panel, the manufacturing method thereof, and the display device provided by the embodiments of the present disclosure, the following detailed description is given in conjunction with the accompanying drawings.

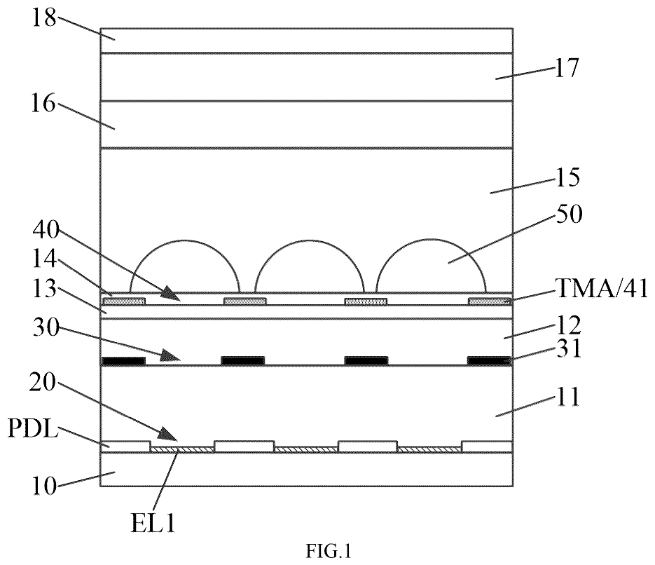

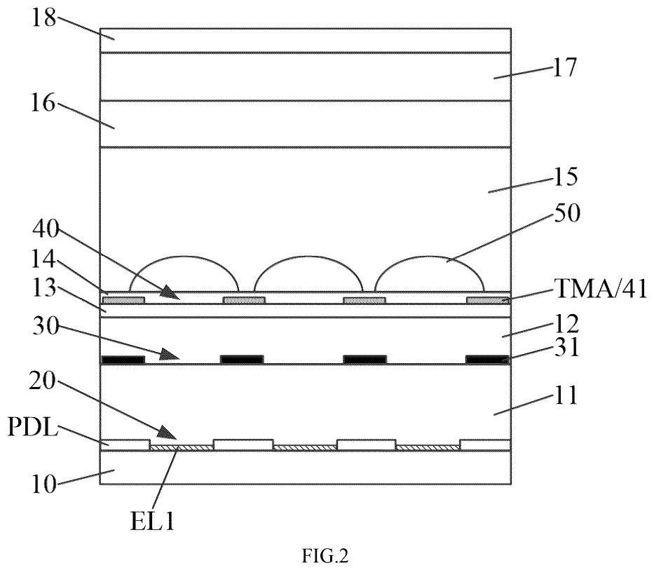

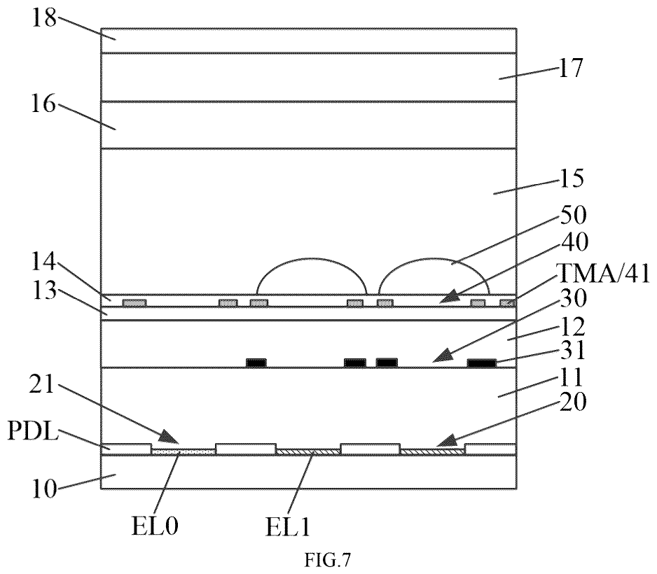

Referring to FIGS. 1 to 7, an embodiment of the present disclosure provides a touch display panel that includes: a base substrate 10 and a plurality of sub-pixels disposed on the base substrate 10. The plurality of sub-pixels include a plurality of sharing sub-pixels (e.g., red sharing sub-pixel P-R1, green sharing sub-pixel P-G1, and blue sharing sub-pixel P-B1) and a plurality of anti-peeping sub-pixels (e.g., red anti-peeping sub-pixel P-R2, green anti-peeping sub-pixel P-G2, and blue anti-peeping sub-pixel P-B2). Each anti-peeping sub-pixel includes at least two anti-peeping pixel apertures 20. The touch display panel further includes:
a first light-shielding layer 31, which defines a plurality of first apertures 30; an orthographic projection of each first aperture 30 on the base substrate 10 at least partially overlaps with an orthographic projection of a corresponding anti-peeping pixel aperture 20 on the base substrate 10; and at least part of an orthographic projection of the first light-shielding layer 31 on the base substrate 10 is located at a periphery of an orthographic projection of at least part of the anti-peeping pixel apertures 20 on the base substrate 10;
a touch layer (e.g., touch electrode layer TMA and/or touch electrode layer TMB), where the touch layer is located on a side of the first light-shielding layer 31 facing away from the base substrate 10,
where the touch layer is reused as a second light-shielding layer 41 whose orthographic projection on the base substrate 10 defines a plurality of second apertures 40; each second aperture 40 at least partially overlaps with an orthographic projection of a corresponding anti-peeping pixel aperture 20 on the base substrate 10; and at least part of the orthographic projection of the second light-shielding layer 41 on the base substrate 10 is located at a periphery of the orthographic projection of at least part of the anti-peeping pixel apertures 20 on the base substrate 10.

It should be noted that the reference numerals 11, 12, 13, 14, and 15 in the drawings all represent insulating layers. Reference numeral 16 represents optical clear adhesive (OCA), reference numeral 17 represents a cover plate, and reference numeral 18 represents a hard coating (HC) layer.

Exemplarily, the plurality of sharing sub-pixels include a plurality of red sharing subpixels, a plurality of green sharing sub-pixels, and a plurality of blue sharing sub-pixels. These sharing sub-pixels are grouped into a plurality of sharing pixel units distributed in an array, and at least part of the sharing pixel units include one red sharing sub-pixel, one green sharing subpixel, and one blue sharing sub-pixel. The plurality of anti-peeping sub-pixels include a plurality of red anti-peeping sub-pixels, a plurality of green anti-peeping sub-pixels, and a plurality of blue anti-peeping sub-pixels. These anti-peeping sub-pixels are grouped into a plurality of anti-peeping pixel units distributed in an array, and each anti-peeping pixel unit includes one red anti-peeping sub-pixel, one green anti-peeping sub-pixel, and one blue anti-peeping sub-pixel.

Exemplarily, the sharing pixel units and the anti-peeping pixel units are alternately arranged along at least one direction, but not limited thereto.

Exemplarily, the plurality of sharing sub-pixels are grouped into a plurality of sharing pixel units, each including at least two sharing sub-pixels. The plurality of anti-peeping subpixels are grouped into a plurality of anti-peeping pixel units, each including at least two anti-peeping sub-pixels.

The plurality of sharing pixel units are grouped into a plurality of rows of sharing pixel unit rows, the plurality of anti-peeping pixel units are grouped into a plurality of rows of anti-peeping pixel unit rows, and the sharing pixel unit rows and the anti-peeping pixel unit rows are alternately arranged. Exemplarily, the number of anti-peeping pixel units may or may not be equal to the number of sharing pixel units; no limitation is imposed herein.

Exemplarily, each anti-peeping sub-pixel includes at least two anti-peeping pixel apertures 20, and the anti-peeping pixel apertures 20 are independent of each other. For example: each anti-peeping sub-pixel includes a plurality of anti-peeping pixel apertures 20 that are distributed in an array and independent of each other. Exemplarily, each sharing sub-pixel includes one sharing pixel aperture 21, but not limited thereto. Exemplarily, the outline of each anti-peeping pixel aperture 20 is circular, and the outline of each sharing pixel aperture 21 is rectangular, but not limited thereto.

Exemplarily, in the touch display panel, there are more anti-peeping pixel apertures 20 than sharing pixel apertures 21, and a single anti-peeping pixel aperture 20 covers less area than a single sharing pixel aperture 21.

Exemplarily, the area of the anti-peeping pixel apertures corresponding to one red anti-peeping sub-pixel is smaller than the area of the anti-peeping pixel apertures corresponding to one blue anti-peeping sub-pixel; the area of the anti-peeping pixel apertures corresponding to one blue anti-peeping sub-pixel is smaller than the area of the anti-peeping pixel apertures corresponding to one green anti-peeping sub-pixel.

Exemplarily, the area of the sharing pixel aperture corresponding to one red sharing sub-pixel is smaller than the area of the sharing pixel aperture corresponding to one blue sharing sub-pixel; the area of the sharing pixel aperture corresponding to one blue sharing sub-pixel is smaller than the area of the sharing pixel aperture corresponding to one green sharing sub-pixel.

Exemplarily, the anode included in each anti-peeping sub-pixel is independent of the anode included in each sharing sub-pixel. The light-emitting material layer EL1 included in each anti-peeping sub-pixel and the light-emitting material layer EL0 included in each sharing sub-pixel can be shared, that is, both layers can be formed into an integrated structure. The anti-peeping sub-pixels and the sharing sub-pixels share the same cathode layer.

Exemplarily, the parts of the anode exposed corresponding to the anti-peeping pixel apertures 20 in the same anti-peeping sub-pixel are formed into an integrated structure, that is, one anti-peeping sub-pixel includes one independent anode that corresponds to the anti-peeping pixel apertures 20 included in the anti-peeping sub-pixel. For example: the parts of the anode exposed corresponding to the anti-peeping pixel apertures 20 in the same red anti-peeping subpixel are formed into an integrated structure. The parts of the anodes exposed corresponding to the anti-peeping pixel apertures 20 in the same green anti-peeping sub-pixel are formed into an integrated structure. The parts of the anodes exposed corresponding to the anti-peeping pixel apertures 20 in the same blue anti-peeping sub-pixel are formed into an integrated structure.

Exemplarily, both the sharing sub-pixels and the anti-peeping sub-pixels can adopt an S-stripe RGB pixel arrangement, but not limited thereto.

Exemplarily, both the sharing sub-pixels and the anti-peeping sub-pixels include subpixel driving circuits, and the sub-pixel driving circuits included in the sharing sub-pixels and the anti-peeping sub-pixels together form a driving circuit layer in the touch display panel. The touch display panel further includes a pixel defining layer (PDL), which is located on a side of the driving circuit layer facing away from the base substrate 10 and used to define anti-peeping pixel apertures 20 and sharing pixel apertures 21 above the anode to expose the same. The pixel defining layer (PDL) can be made of a black pixel defining material or a transparent pixel defining material.

Exemplarily, the touch display panel further includes a thin-film encapsulation layer on a side of the cathode layer facing away from the base substrate 10. The thin-film encapsulation layer includes three encapsulation layers—for example, an inorganic encapsulation layer, an organic encapsulation layer, and an inorganic encapsulation layer—stacked in the same order. Alternatively, the thin-film encapsulation layer includes a plurality of stacked encapsulation layers. Exemplarily, the thickness of the thin-film encapsulation layer is between 6 micrometers and 20 micrometers, inclusive of the end-point values, but not limited thereto.

Exemplarily, the first light-shielding layer 31 is located on a side of the thin-film encapsulation layer facing away from the base substrate 10, and the first light-shielding layer 31 can be made of a black matrix material or other light-shielding materials. Along a direction perpendicular to the base substrate 10, the distance between the first light-shielding layer 31 and the sub-pixels is between 6 micrometers and 12 micrometers, preferably between 8 micrometers and 10 micrometers. The thickness of the first light-shielding layer 31 is between 1 micrometer and 3 micrometers. Exemplarily, the first light-shielding layer 31 defines a plurality of first apertures 30, and the first apertures 30 are in one-to-one correspondence with the anti-peeping pixel apertures 20. By arranging both the first light-shielding layer 31 and the touch layer on the side of the thin-film encapsulation layer facing away from the base substrate 10, the touch display panel is formed into a structure with an On-cell touch layer.

Exemplarily, the second light-shielding layer 41 is located on a side of the first light-shielding layer 31 facing away from the base substrate 10. Along a direction perpendicular to the base substrate 10, the distance between the second light-shielding layer 41 and the subpixels is between 10 micrometers and 30 micrometers, inclusive of the end-point values, but is not limited thereto.

According to the specific structure of the above touch display panel, in the touch display panel provided by the embodiment of the present disclosure, the first light-shielding layer 31 and the second light-shielding layer 41 are disposed on the side of the anti-peeping pixel aperture 20 facing away from the base substrate 10. The first light-shielding layer 31 defines first apertures 30 corresponding to the anti-peeping pixel apertures 20, and the second light-shielding layer 41 defines second apertures 40 corresponding to the anti-peeping pixel apertures 20. The light emitted from the anti-peeping pixel apertures 20 exits the touch display panel through the first apertures 30 and the second apertures 40 in sequence, thereby realizing the anti-peeping mode of the touch display panel.

In more detail, in the touch display panel provided by the embodiment of the present disclosure, by arranging the first light-shielding layer 31 to define a plurality of first apertures 30, where an orthographic projection of each first aperture 30 on the base substrate 10 at least partially overlaps with an orthographic projection of a corresponding anti-peeping pixel aperture 20 on the base substrate 10, and at least part of an orthographic projection of the first light-shielding layer 31 on the base substrate 10 is located at a periphery of an orthographic projection of at least part of the anti-peeping pixel apertures 20 on the base substrate 10. The first light-shielding layer 31 restricts the light emitted from the anti-peeping pixel apertures 20, so that the light can only exit to the light-emitting side of the touch display panel from the first apertures 30. Meanwhile, by arranging the orthographic projection of the second light-shielding layer 41 on the base substrate 10 to define a plurality of second apertures 40, where each second aperture 40 at least partially overlaps with an orthographic projection of a corresponding anti-peeping pixel aperture 20 on the base substrate 10, and at least part of the orthographic projection of the second light-shielding layer 41 on the base substrate 10 is located at a periphery of the orthographic projection of at least part of the anti-peeping pixel apertures 20 on the base substrate 10. The second light-shielding layer 41 further restricts the transmission path of the light emitted from the first apertures 30, so that the light can only exit to the light-emitting side of the touch display panel via the second apertures 40, thereby enabling the touch display panel to realize the anti-peeping mode through the anti-peeping sub-pixels.

In the touch display panel provided by the embodiment of the present disclosure, 110 first light-shielding layer 31 is arranged on the light-emitting side of the sharing pixel apertures 21, that is, the orthographic projection of the first light-shielding layer 31 on the base substrate 10 does not overlap with the orthographic projection of the sharing pixel apertures 21 on the base substrate 10, and the orthographic projection of the first light-shielding layer 31 on the base substrate 10 is not located at the periphery of the orthographic projection of the sharing pixel apertures 21 on the base substrate 10. Therefore, the first light-shielding layer 31 does not obstruct the transmission path of the light emitted from the sharing pixel apertures 21, enabling the touch display panel to realize the sharing mode through the sharing sub-pixels.

Moreover, in the touch display panel provided by the embodiment of the present disclosure, the touch layer located on the side of the first light-shielding layer 31 facing away from the base substrate 10 is reused as the second light-shielding layer 41, which avoids forming a dedicated second light-shielding layer 41 in the touch display panel, hence reducing the number of film layers inside the touch display panel. This optimizes the internal structure of the touch display panel and addresses the challenges of complex designs, excessive thickness, and high manufacturing cost of the display product when enabling switching between the anti-peeping mode and the screen sharing mode.

In some embodiments, the orthographic projection of the boundary of each anti-peeping pixel aperture 20 on the base substrate 10 is surrounded by the orthographic projection of the boundary of a corresponding first aperture 30 on the base substrate 10; or at least part of the orthographic projection of the boundary of each anti-peeping pixel aperture 20 on the base substrate 10 is located within the orthographic projection of the first light-shielding layer 31 on the base substrate 10; and/or the orthographic projection of the boundary of each anti-peeping pixel aperture 20 on the base substrate 10 is surrounded by the boundary of a corresponding second aperture 40; or at least part of the orthographic projection of the boundary of each anti-peeping pixel aperture 20 on the base substrate 10 is located inside the orthographic projection of the second light-shielding layer 41 on the base substrate 10.

Exemplarily, the orthographic projection of each anti-peeping pixel aperture 20 on the base substrate 10 is located within the orthographic projection of a corresponding first aperture 30 on the base substrate 10; or the orthographic projection of the boundary of each anti-peeping pixel aperture 20 on the base substrate 10 surrounds the orthographic projection of a corresponding first aperture 30 on the base substrate 10.

Exemplarily, the orthographic projection of each anti-peeping pixel aperture 20 on the base substrate 10 is located within the orthographic projection of a corresponding second aperture 40 on the base substrate 10; or the orthographic projection of the boundary of each anti-peeping pixel aperture 20 on the base substrate 10 surrounds the orthographic projection of a corresponding second aperture 40 on the base substrate 10.

Exemplarily, the distance between the orthographic projection of the boundary of each anti-peeping pixel aperture 20 on the base substrate 10 and the orthographic projection of the boundary of a corresponding first aperture 30 on the base substrate 10 is between −3 micrometers and 10 micrometers, or between −1 micrometers and 10 micrometers, or preferably between 0 and 6 micrometers. The above ranges may all include the end-point values.

Exemplarily, the distance between the orthographic projection of the boundary of each anti-peeping pixel aperture 20 on the base substrate 10 and the orthographic projection of the boundary of a corresponding second aperture 40 on the base substrate 10 is between −3 micrometers and 10 micrometers, preferably between 0 and 6 micrometers. The above ranges may all include the end-point values.

It should be noted that when the above distance is positive, it means that the orthographic projection of the boundary of the anti-peeping pixel aperture 20 on the base substrate 10 does not overlap with the orthographic projection of the light-shielding layer on the base substrate 10. When the above distance is negative, it means that the orthographic projection of the boundary of the anti-peeping pixel aperture 20 on the base substrate 10 overlaps with the orthographic projection of the light-shielding layer on the base substrate 10.

The above arrangement enables the light emitted from the anti-peeping pixel apertures 20 to exit the touch display panel through the first apertures 30 and the second apertures 40 in sequence, thereby realizing the anti-peeping mode of the touch display panel.

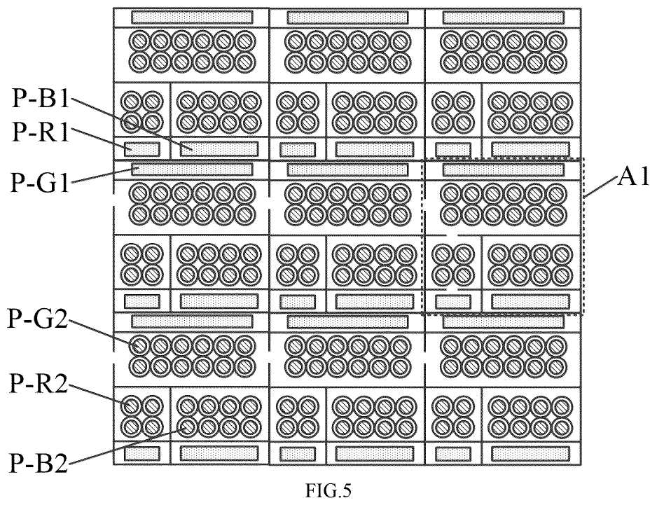

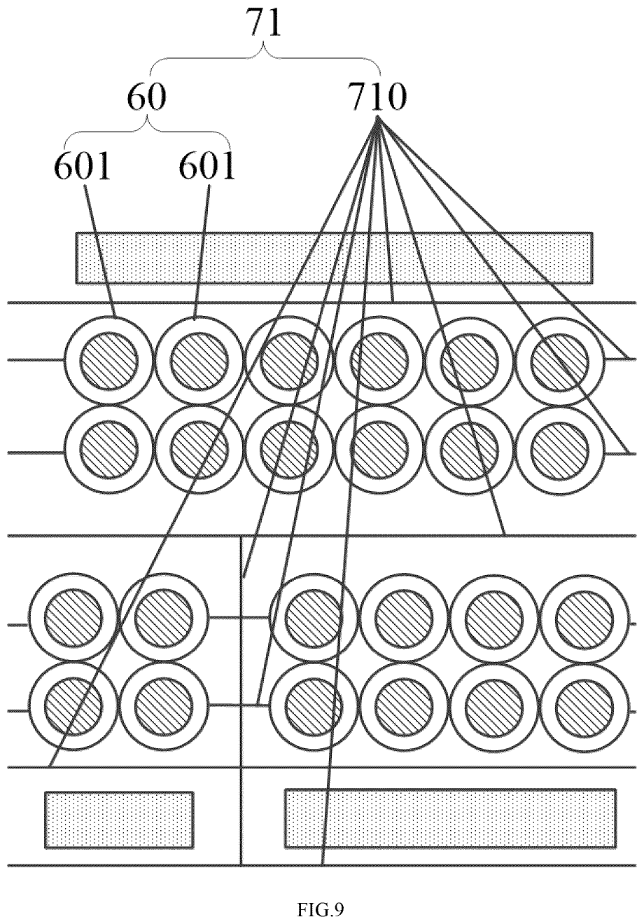

As shown in FIGS. 5 to 10, in some embodiments, the second apertures 40 corresponding to the anti-peeping pixel apertures 20 for the same anti-peeping sub-pixel may together serve as one aperture unit. The touch layer includes a plurality of light-shielding parts 60, and an orthographic projection of each light-shielding part 60 on the base substrate 10 defines a corresponding aperture unit; the plurality of light-shielding parts 60 are independent of each other, or at least two of the light-shielding parts 60 are coupled.

Exemplarily, each light-shielding part 60 includes at least two sub-portions 601. An orthographic projection of a sub-portion 601 on the base substrate 10 defines a corresponding second aperture 40. The sub-portions 601 belonging to the same light-shielding part 60 are independent of each other. Or, at least two of the sub-portions 601 belonging to the same light-shielding part 60 are coupled.

The above arrangement enables the light-shielding parts 60 to better define the second apertures 40 located above the anti-peeping pixel apertures 20, so that the light emitted from the first apertures 30 can only exit from the light-emitting side of the touch display panel through the second apertures 40, thereby enabling the touch display panel to realize the anti-peeping mode.

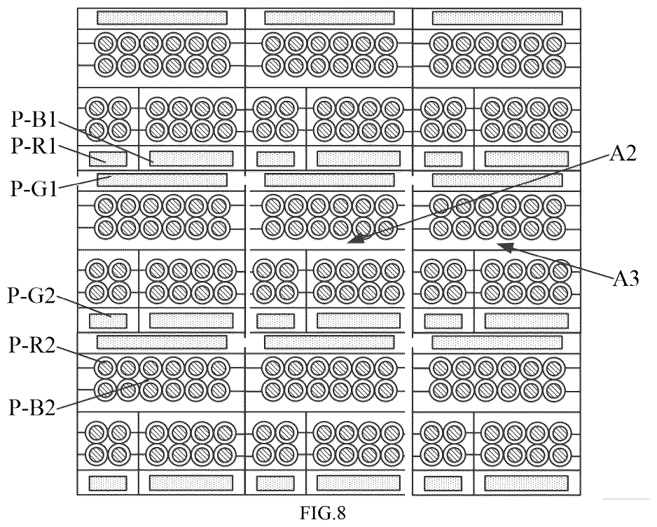

As shown in FIGS. 8 to 10, in some embodiments, the touch layer includes independent touch electrodes 70 and dummy electrodes 71, with at least one of the touch electrodes 70 and the dummy electrodes 71 including the light-shielding parts 60.

Exemplarily, both the touch electrodes 70 and the dummy electrodes 71 are made of conductive material, such as metal material, but is not limited thereto. The touch electrodes 70 are used to drive or receive touch signals and can realize the touch function. The dummy electrodes 71 include floating electrodes and do not receive electrical signals. Note that the dummy electrodes 71 may be included optionally, depending on specific requirements.

By arranging the touch layer to include independent touch electrodes 70 and dummy electrodes 71, the touch signal strength is optimized, and the touch performance is improved. By arranging at least one of the touch electrodes 70 and the dummy electrodes 71 to include the light-shielding parts 60, no dedicated second light-shielding layer 41 for light restricting is needed in the touch display panel, reducing the number of film layers inside the touch display panel, optimizing the internal structure of the touch display panel, and addressing the challenges of complex design, excessive thickness, and high manufacturing cost of display products when enabling the feature of switching between the anti-peeping mode and the screen sharing mode.

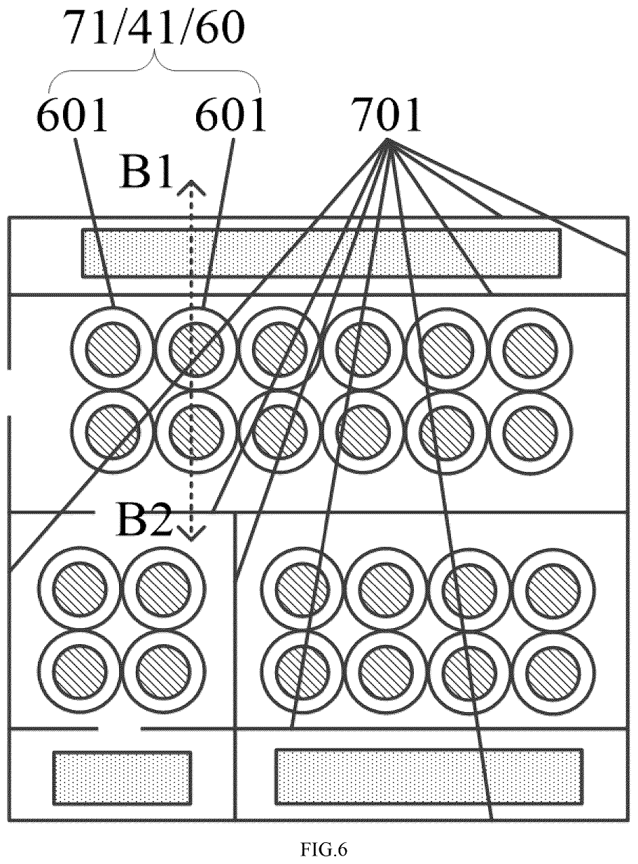

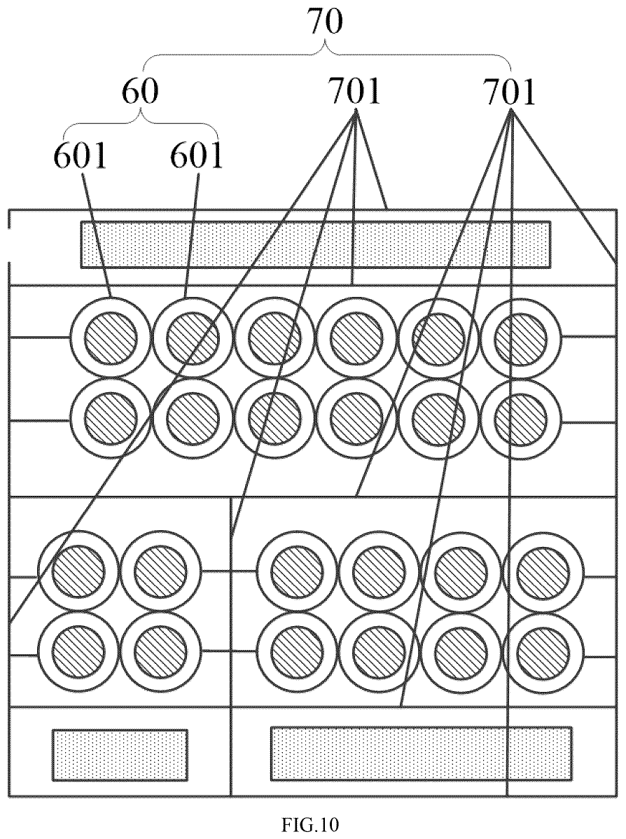

As shown in FIG. 10, in some embodiments, each touch electrode 70 includes an effective electrode portion 701, to which the light-shielding part 60 included in each touch electrode 70 is coupled; and/or, as shown in FIG. 6, the light-shielding part 60 included in each dummy electrode 71 is independent of the effective electrode portion 701.

The effective electrode portion 701 is mainly used to realize the touch function. The light-shielding part 60 included in each touch electrode 70 is coupled to the effective electrode portion 701, so that the light-shielding part 60 can increase the area of the effective electrode portion 701 in addition to realizing its light-shielding function, thereby enhancing the touch signal amount, optimizing the touch signal strength, which in tum improves the touch performance.

The above arrangement that the light-shielding part 60 included in each dummy electrode 71 is independent of the effective electrode portion 701 enables the light-shielding part 60 included in each dummy electrode 71 to optimize the touch signal strength and improve the touch performance while realizing its light-shielding function.

As shown in FIGS. 8 and 10, in some embodiments, each touch electrode 70 includes an effective electrode portion 701. In the case where the light-shielding part 60 included in each touch electrode 70 is coupled to the effective electrode portion 701, the area of the touch electrode part (including the light-shielding part 60 and the effective electrode portion 701) around one red anti-peeping sub-pixel is smaller than the area of the touch electrode part around one blue anti-peeping sub-pixel, and the area of the touch electrode part around one blue anti-peeping sub-pixel is smaller than the area of the touch electrode part around one green anti-peeping sub-pixel.

As shown in FIG. 10, in some embodiments, the orthographic projection of the light-shielding part 60 included in each touch electrode 70 on the base substrate 10 is at least partially surrounded by the orthographic projection of the effective electrode portion 701 on the base substrate 10; and/or, as shown in FIG. 6, the orthographic projection of the light-shielding part 60 included in each dummy electrode 71 on the base substrate 10 is at least partially surrounded by the orthographic projection of the effective electrode portion 701 on the base substrate 10.

The above arrangement not only ensures the light-shielding performance of the light-shielding parts 60, but also ensures sufficient space for positioning the effective electrode portion 701, thereby maintaining the touch performance of the touch display panel.

In some embodiments, as shown in FIGS. 5 to 9, each dummy electrode 71 includes an ineffective electrode portion 710, at least some of which are coupled to the light-shielding part 60 included in each dummy electrode 71. Or, the light-shielding part 60 included in each dummy electrode 71 may be independent of the ineffective electrode portion 710.

The above different layout plans can be selected according to actual requirements. The light-shielding part 60 included in each dummy electrode 71 can, whether being coupled to the ineffective electrode portion 710, achieve the technical effects of enhancing the touch signal strength and improving the touch performance.

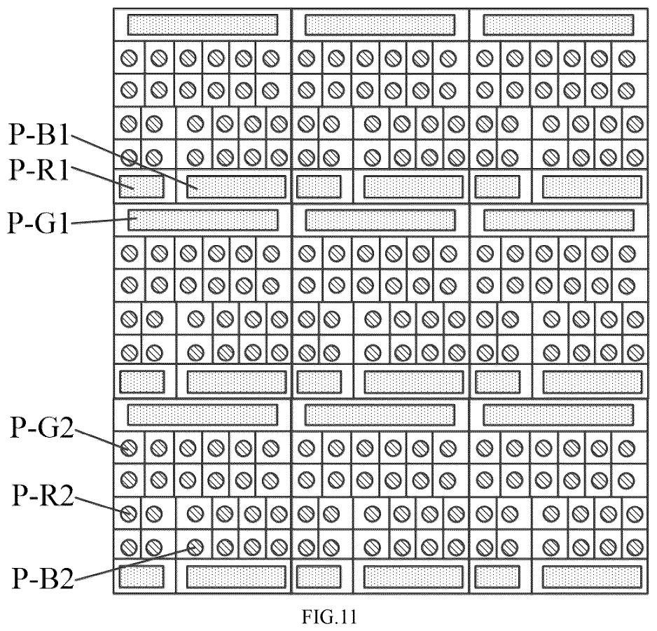

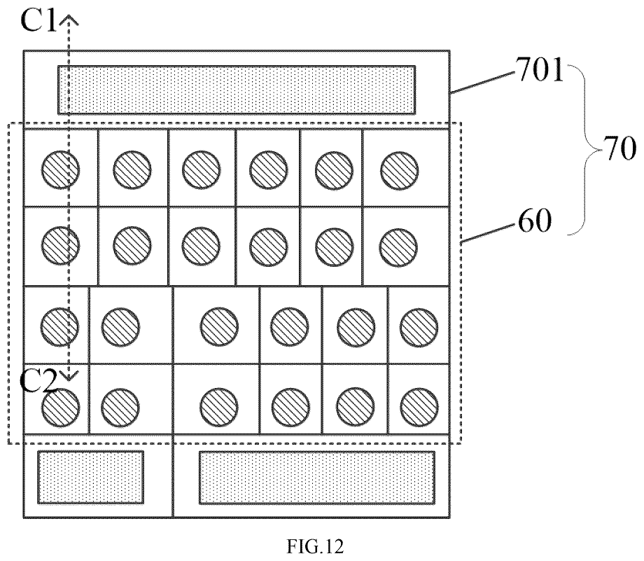

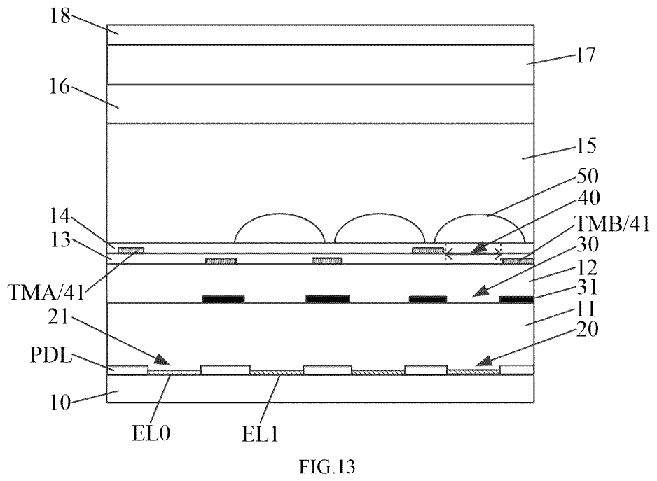

As shown in FIGS. 11 to 13, in some embodiments, the orthographic projection of each light-shielding part 60 on the base substrate 10 is formed into a grid structure, and each grid in the grid structure correspondingly defines one second aperture 40.

Exemplarily, each touch electrode 70 includes an effective electrode portion 701, at least part of which is reused as the light-shielding part 60. Exemplarily, the dummy electrodes 71 are reused as the light-shielding parts 60 having a grid structure.

The above arrangement that the light-shielding parts 60 are in a grid structure, with each grid in the grid structure correspondingly defining one second aperture 40 effectively simplifies the structure of the light-shielding parts 60, increases the layout space of the touch electrodes 70, and thereby reduces the layout difficulty of the touch electrodes 70.

In some embodiments, the grids corresponding to anti-peeping sub-pixels of different colors have different dimensions. For example, the grid size corresponding to red anti-peeping sub-pixels is smaller than the grid size corresponding to green anti-peeping sub-pixels, and the grid size corresponding to blue anti-peeping sub-pixels is smaller than the grid size corresponding to green anti-peeping sub-pixels, but not limited thereto.

As shown in FIGS. 1 to 4, in some embodiments, the touch layer includes at least one touch electrode layer (e.g., touch electrode layer TMA and touch electrode layer TMB), and the touch electrode layer is reused as the second light-shielding layer 41.

Exemplarily, the touch electrode layer includes independent touch electrodes 70 and dummy electrodes 71.

Exemplarily, the touch layer includes one or two metal grid-shaped touch electrode layers, and the underlying layers of the touch electrode layers may or may not be blackened. The blackening treatment can be realized by forming a black matrix.

Exemplarily, when the touch layer includes two touch electrode layers, a dielectric layer can be formed between the two touch electrode layers. The dielectric layer can be made of an inorganic material, such as SiNx and/or SiOx. It can also be made of an organic material. The thickness of the touch layer is between 0.1 micrometers and 5 micrometers, for example, optionally between 0.1 micrometers and 2 micrometers, but not limited thereto. The grid size of the grid structure formed by the light-shielding parts 60 is between 3 micrometers and 20 micrometers.

Exemplarily, the touch layer includes a first touch electrode layer (e.g., TMB) and a second touch electrode layer (e.g., TMA) that are sequentially stacked along a direction away from the base substrate 10. At least one of the first touch electrode layer and the second touch electrode layer is reused as the second light-shielding layer 41.

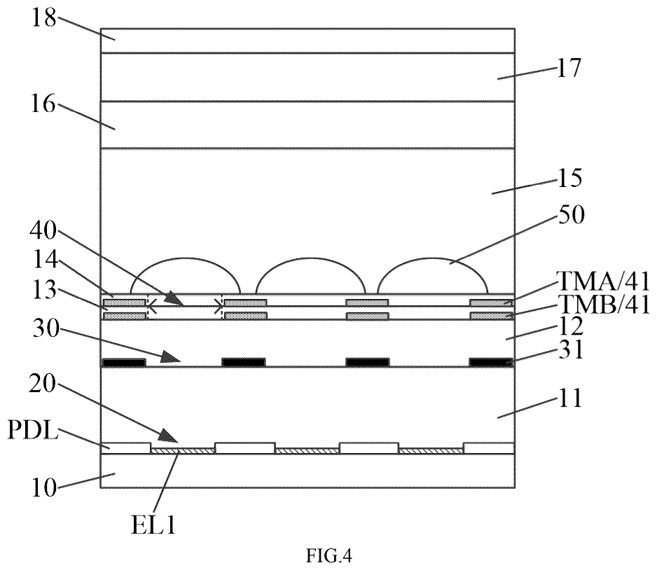

As shown in FIG. 4, in some embodiments, the touch layer includes a first touch electrode layer (e.g., TMB) and a second touch electrode layer (e.g., TMA) that are sequentially stacked along a direction away from the base substrate 10. The touch display panel includes two stacked second light-shielding layers 41, the first touch electrode layer is reused as one second light-shielding layer 41, and the second touch electrode layer is reused as the other second light-shielding layer 41.

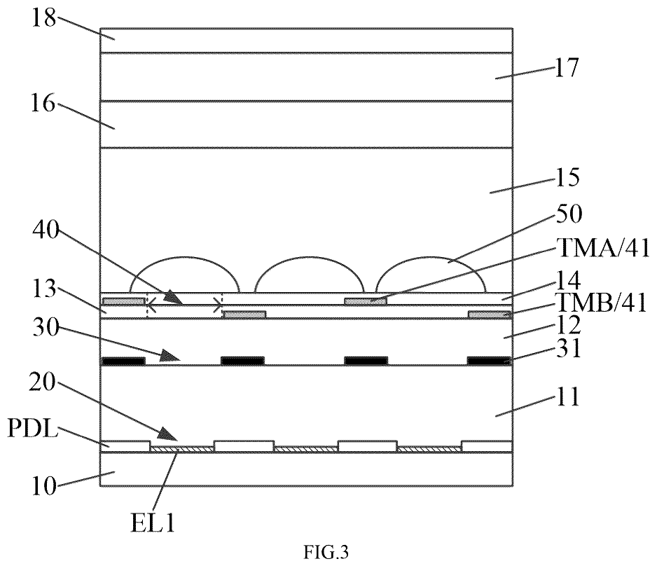

As shown in FIGS. 3, 12, and 13, in some embodiments, the touch layer includes a first touch electrode layer (e.g., TMB) and a second touch electrode layer (e.g., TMA) that are sequentially stacked along a direction away from the base substrate 10. The first touch electrode layer is reused as a part of the second light-shielding layer 41, and the second touch electrode layer is reused as another part of the second light-shielding layer 41.

Exemplarily, at least one second aperture 40 is jointly defined by an orthographic projection of the first touch electrode layer on the base substrate 10 and an orthographic projection of the second touch electrode layer on the base substrate 10.

As shown in FIG. 3, exemplarily, the orthographic projection of the part of the second touch electrode layer (e.g., TMA) reused as the second light-shielding layer 41 on the base substrate overlaps with the orthographic projections of two adjacent lens structures 50 on the base substrate.

The above arrangement not only ensures the light-shielding performance of the second light-shielding layer 41, but also ensures the touch performance of the first touch layer and the second touch layer.

In some embodiments, when at least one of the first touch electrode layer (e.g., TMB) and the second touch electrode layer (e.g., TMA) is reused as the second light-shielding layer 41, the size of the second apertures defined by the second light-shielding layer 41 is smaller than the size of the first apertures defined by the first light-shielding layer. For example, the orthographic projection of each second aperture on the base substrate is located inside the orthographic projection of a corresponding first aperture on the base substrate, but not limited thereto.

In some embodiments, when at least one of the first touch electrode layer (e.g., TMB) and the second touch electrode layer (e.g., TMA) is reused as the second light-shielding layer 41, the size of the second apertures defined by the second light-shielding layer 41 is larger than the size of the first apertures defined by the first light-shielding layer. For example, the orthographic projection of each second aperture on the base substrate completely covers the orthographic projection of a corresponding first aperture on the base substrate, but not limited thereto.

In some embodiments, when at least one of the first touch electrode layer (e.g., TMB) and the second touch electrode layer (e.g., TMA) is reused as the second light-shielding layer 41, the size of the second apertures defined by the second light-shielding layer 41 is equal to the size of the first apertures defined by the first light-shielding layer. For example: the orthographic projection of each second aperture on the base substrate coincides with the orthographic projection of a corresponding first aperture on the base substrate, but not limited thereto.

As shown in FIGS. 1 to 4, in some embodiments, the touch display panel further includes: a plurality of lens structures 50 located on a side of the touch layer facing away from the base substrate 10. An orthographic projection of each lens structure 50 on the base substrate 10 covers an orthographic projection of a corresponding anti-peeping pixel aperture 20 on the base substrate 10.

Exemplarily, the lens structures 50 are in one-to-one correspondence with the anti-peeping pixel apertures 20; the orthographic projection of each anti-peeping pixel aperture 20 on the base substrate 10 is located inside the orthographic projection of a corresponding lens structure 50 on the base substrate 10; and the orthographic projection of each anti-peeping pixel aperture 20 on the base substrate 10 is surrounded by the boundary of the orthographic projection of a corresponding lens structure 50 on the base substrate 10.

Exemplarily, the lens structures 50 are made of a high-refractive-index material, and the refractive index of the lens structures 50 is between 1.3 and 1.9, inclusive of the end-point values. The periphery of the lens structures 50 is made of a low-refractive-index material, with a refractive index between 1.1 and 1.7. The lens structures 50 include hemispherical structures and spherical cap structures. The bottom diameter of the lens structures 50 is between 6 micrometers and 40 micrometers, and the bottom diameter of the lens structures 50 is larger than the diameter of the anti-peeping pixel apertures 20. The lens structures 50 may be in direct contact with the second light-shielding layer 41, or there may be an inorganic film layer or an organic film layer between the lens structures 50 and the second light-shielding layer 41.

The above arrangement that the touch display panel further includes a plurality of lens structures 50 improves the light-emitting rate of the anti-peeping sub-pixels and the display effect of the touch display panel in the anti-peeping mode.

An embodiment of the present disclosure further provides a display device, including the touch display panel provided by the above embodiments.

Exemplarily, the display device includes an active-matrix organic light-emitting diode (AMOLED) display device, but not limited thereto.

It should be noted that the display device may be any product or component with a display function, such as a television, a display, a digital photo frame, a mobile phone, a tablet computer, etc. The display device may further include a flexible circuit board, a printed circuit board, a backplane, and/or the like.

In the touch display panel provided by the above embodiment, the first light-shielding layer 31 and the second light-shielding layer 41 are disposed on the side of the anti-peeping pixel aperture 20 facing away from the base substrate 10. The first light-shielding layer 31 defines first apertures 30 corresponding to the anti-peeping pixel apertures 20, and the second light-shielding layer 41 defines second apertures 40 corresponding to the anti-peeping pixel apertures 20. The light emitted from the anti-peeping pixel apertures 20 exits the touch display panel through the first apertures 30 and the second apertures 40 in the same order, thereby realizing the anti-peeping mode of the touch display panel. Moreover, in the touch display panel provided by the above embodiment, the touch layer located on the side of the first light-shielding layer 31 facing away from the base substrate 10 is reused as the second light-shielding layer 41, which avoids forming a dedicated second light-shielding layer 41 in the touch display panel, reduces the number of film layers inside the touch display panel, optimizes the internal structure of the touch display panel, and addresses the challenges of complex design, excessive thickness, and high manufacturing cost of display products for enabling the feature of switching between the anti-peeping mode and the screen sharing mode.

Therefore, the display device provided by the embodiment of the present disclosure also has the above beneficial effects when the above touch display panel is included, the details of which will not be repeated herein.

An embodiment of the present disclosure further provides a method of manufacturing a touch display panel, including:
forming a plurality of sub-pixels on a base substrate, where the plurality of sub-pixels include a plurality of sharing sub-pixels and a plurality of anti-peeping sub-pixels, and each anti-peeping sub-pixel includes at least two anti-peeping pixel apertures;
forming a first light-shielding layer on a side of the plurality of sub-pixels facing away from the base substrate, where the first light-shielding layer defines a plurality of first apertures, an orthographic projection of each first aperture on the base substrate at least partially overlaps with an orthographic projection of a corresponding anti-peeping pixel aperture on the base substrate, and at least part of an orthographic projection of the first light-shielding layer on the base substrate is located at a periphery of an orthographie projection of at least part of the anti-peeping pixel apertures on the base substrate; and
forming a touch layer on a side of the first light-shielding layer facing away from the base substrate, where the touch layer is reused as a second light-shielding layer; an orthographic projection of the second light-shielding layer on the base substrate defines a plurality of second apertures; each second aperture at least partially overlaps with an orthographic projection of a corresponding anti-peeping pixel aperture on the base substrate; and at least part of the orthographic projection of the second light-shielding layer on the base substrate is located at a periphery of the orthographic projection of at least part of the anti-peeping pixel apertures on the base substrate.

In the touch display panel manufactured by the manufacturing method provided by the embodiment of the present disclosure, the first light-shielding layer 31 and the second light-shielding layer 41 are disposed on the side of the anti-peeping pixel aperture 20 facing away from the base substrate 10. The first light-shielding layer 31 defines first apertures 30 corresponding to the anti-peeping pixel apertures 20, and the second light-shielding layer 41 defines second apertures 40 corresponding to the anti-peeping pixel apertures 20. The light emitted from the anti-peeping pixel apertures 20 exits the touch display panel through the first apertures 30 and the second apertures 40 in sequence, thereby realizing the anti-peeping mode of the touch display panel.

In more details, in the touch display panel manufactured by the manufacturing method provided by the embodiment of the present disclosure, the first light-shielding layer 31 defines a plurality of first apertures 30. An orthographic projection of each first aperture 30 on the base substrate 10 at least partially overlaps with an orthographic projection of a corresponding anti-peeping pixel aperture 20 on the base substrate 10. At least part of an orthographic projection of the first light-shielding layer 31 on the base substrate 10 is located at a periphery of an orthographic projection of at least part of the anti-peeping pixel apertures 20 on the base substrate 10. These enable the first light-shielding layer 31 to restrict the light emitted from the anti-peeping pixel apertures 20, so that the light can only exit from the light-emitting side of the touch display panel through the first apertures 30. Meanwhile, the orthographic projection of the second light-shielding layer 41 on the base substrate 10 defines a plurality of second apertures 40, each at least partially overlaps with an orthographic projection of a corresponding anti-peeping pixel aperture 20 on the base substrate 10. At least part of the orthographic projection of the second light-shielding layer 41 on the base substrate 10 is located at a periphery of the orthographic projection of at least part of the anti-peeping pixel apertures 20 on the base substrate 10. These enable the second light-shielding layer 41 to further restrict the transmission path of the light emitted from the first apertures 30, so that the light can only exit from the light-emitting side of the touch display panel through the second apertures 40, thereby enabling the touch display panel to realize the anti-peeping mode through the anti-peeping subpixels.

In the touch display panel manufactured by the manufacturing method provided by the embodiment of the present disclosure, no first light-shielding layer 31 is arranged on the light-emitting side of the sharing pixel apertures 21, that is, the orthographic projection of the first light-shielding layer 31 on the base substrate 10 does not overlap with the orthographic projection of the sharing pixel apertures 21 on the base substrate 10, and the orthographic projection of the first light-shielding layer 31 on the base substrate 10 is not located at the periphery of the orthographic projection of the sharing pixel apertures 21 on the base substrate 10. Therefore, the first light-shielding layer 31 does not obstruct the transmission path of the light emitted from the sharing pixel apertures 21, enabling the touch display panel to realize the sharing mode through the sharing sub-pixels.

Moreover, in the touch display panel manufactured by the manufacturing method provided by the embodiment of the present disclosure, the touch layer located on the side of the first light-shielding layer 31 facing away from the base substrate 10 is reused as the second light-shielding layer 41, which avoids forming a dedicated second light-shielding layer 41 in the touch display panel, thereby reducing the number of film layers inside the touch display panel, optimizing the internal structure of the touch display panel, and addresses the challenges of complex design, excessive thickness, and high manufacturing cost of display products for enabling the feature of switching between the anti-peeping mode and the screen sharing mode.

It should be noted that “in the same layer” in the embodiments of the present disclosure may mean film layers sharing a common structural layer. Alternatively, for example, film layers in the same layer may be formed by the same film-forming process for forming specific patterns, and then patterned by one patterning process using the same mask to form a layer structure. Depending on the specific patterns, one patterning process may include a plurality of exposure, development, or etching processes, and the specific patterns in the formed layer structure may be continuous or discontinuous. These specific patterns may also be located at various levels or have different thicknesses.

In the method embodiments of the present disclosure, the numbering of the steps cannot be used to limit the sequence of the steps. For those of ordinary skill in the art, changes to the sequence of the steps without exerting creative efforts should also fall within the protection scope of the present disclosure.

It is to be noted that the various embodiments in this specification are described in a progressive manner, and the same or similar portions among the various embodiments may be referenced to each other. Individual embodiments are described to highlight their differences from others. In particular, the method embodiments have relatively simple descriptions because they are essentially similar to the product embodiments, and the related portions can be referenced to the description of the product embodiments.

Unless otherwise defined, the technical terms or scientific terms used in the present disclosure shall have the usual meanings understood by those with ordinary skills in the field to which the present disclosure pertains. The phrases “first”, “second” and the like as used in the present disclosure do not indicate any order, quantity, or importance, but are only used to distinguish different components. The phrases “including”, “comprising” and the like mean that the elements or items preceding the phrases include the elements or items (and their equivalents) entailing the phrases, but do not exclude other elements or items. The phrases “connected”, “coupled” or “connected” and similar phrases are not limited to physical or mechanical connections, but may include electrical connections, whether direct or indirect. The phrases “upper”, “lower”, “left”, “right” and the like are only used to indicate relative positional relationships, and when the absolute position of the described object changes, the relative positional relationships may also change accordingly.

It can be understood that when an element such as a layer, film, region, or substrate is described to be “on” or “under” another element, the element can be “directly” on or under the another element, or there may be an intermediate element.

In the description of the above embodiments, specific features, structures, materials, or characteristics can be combined in any one or more embodiments or examples in an appropriate manner.

The above descriptions are only specific implementations of the present disclosure, but the protection scope of the present disclosure is not limited thereto. Any person skilled in the art can easily think of changes or substitutions within the technical scope disclosed in the present disclosure, which should be covered in the protection scope of the present disclosure. Therefore, the protection scope of the present disclosure shall be subject to the protection scope of the claims.

1. A touch display panel, comprising: a base substrate and a plurality of subpixels disposed on the base substrate, wherein the plurality of sub-pixels comprise a plurality of sharing sub-pixels and a plurality of anti-peeping sub-pixels, and each anti-peeping sub-pixel comprises at least two anti-peeping pixel apertures; the touch display panel further comprising:
a first light-shielding layer, wherein the first light-shielding layer defines a plurality of first apertures; an orthographic projection of each first aperture on the base substrate at least partially overlaps with an orthographic projection of a corresponding anti-peeping pixel aperture on the base substrate; and at least part of an orthographic projection of the first light-shielding layer on the base substrate is located at a periphery of an orthographic projection of at least part of the anti-peeping pixel apertures on the base substrate:
a touch layer, wherein the touch layer is located on a side of the first light-shielding layer facing away from the base substrate,
wherein the touch layer is reused as a second light-shielding layer; an orthographic projection of the second light-shielding layer on the base substrate defines a plurality of second apertures; each second aperture at least partially overlaps with an orthographic projection of a corresponding anti-peeping pixel aperture on the base substrate; and at least part of the orthographic projection of the second light-shielding layer on the base substrate is located at a periphery of the orthographic projection of at least part of the anti-peeping pixel apertures on the base substrate.

2. The touch display panel according to claim 1, wherein
an orthographic projection of a boundary of each anti-peeping pixel aperture on the base substrate is surrounded by an orthographic projection of a boundary of a corresponding first aperture on the base substrate; or at least part of the orthographic projection of the boundary of each anti-peeping pixel aperture on the base substrate is located inside the orthographic projection of the first light-shielding layer on the base substrate;
and/or,
an orthographic projection of a boundary of each anti-peeping pixel aperture on the base substrate is surrounded by a boundary of a corresponding second aperture; or at least part of the orthographic projection of the boundary of each anti-peeping pixel aperture on the base substrate is located inside the orthographic projection of the second light-shielding layer on the base substrate.

3. The touch display panel according to claim 1, wherein the second apertures corresponding to the anti-peeping pixel apertures for the same anti-peeping sub-pixel together serve as one aperture unit; the touch layer comprises a plurality of light-shielding parts, with an orthographic projection of each light-shielding part on the base substrate defining a corresponding aperture unit; and the plurality of light-shielding parts are either independent of each other, or at least two of the light-shielding parts are coupled.

4. The touch display panel according to claim 3, wherein each light-shielding part comprises at least two sub-portions; an orthographic projection of each sub-portion on the base substrate defines a corresponding second aperture; the sub-portions belonging to a same light-shielding part are independent of each other, or at least two of the sub-portions belonging to the same light-shielding part are coupled.

5. The touch display panel according to claim 3, wherein the touch layer comprises independent touch electrodes and dummy electrodes, and at least one of the touch electrodes and the dummy electrodes comprises the light-shielding parts.

6. The touch display panel according to claim 5, wherein each touch electrode comprises an effective electrode portion; the light-shielding part comprised in each touch electrode is coupled to the effective electrode portion; and/or the light-shielding part comprised in each dummy electrode is independent of the effective electrode portion.

7. The touch display panel according to claim 6, wherein an orthographic projection of the light-shielding part comprised in each touch electrode on the base substrate is at least partially surrounded by an orthographic projection of the effective electrode portion on the base substrate; and/or an orthographic projection of the light-shielding part comprised in each dummy electrode on the base substrate is at least partially surrounded by the orthographic projection of the effective electrode portion on the base substrate.

8. The touch display panel according to claim 5, wherein each dummy electrode comprises an ineffective electrode portion; the light-shielding part comprised in each dummy electrode is coupled to at least part of the ineffective electrode portion; or the light-shielding part comprised in each dummy electrode is independent of the ineffective electrode portion.

9. The touch display panel according to claim 3, wherein an orthographic projection of each light-shielding part on the base substrate is formed into a grid structure, with each grid in the grid structure correspondingly defining one second aperture.

10. The touch display panel according to claim 9, wherein each touch electrode comprises an effective electrode portion, and at least part of the effective electrode portion is reused as the light-shielding part.

11. The touch display panel according to claim 1, wherein the touch layer comprises at least one touch electrode layer, and the touch electrode layer is reused as the second light-shielding layer.

12. The touch display panel according to claim 1, wherein the touch layer comprises a first touch electrode layer and a second touch electrode layer that are sequentially stacked along a direction away from the base substrate; the touch display panel comprises two stacked second light-shielding layers, the first touch electrode layer being reused as one second light-shielding layer, and the second touch electrode layer being reused as the other second light-shielding layer.

13. The touch display panel according to claim 1, wherein the touch layer comprises a first touch electrode layer and a second touch electrode layer that are sequentially stacked along a direction away from the base substrate; the first touch electrode layer is reused as a part of the second light-shielding layer, and the second touch electrode layer is reused as another part of the second light-shielding layer.

14. The touch display panel according to claim 13, wherein at least one second aperture is jointly defined by an orthographic projection of the first touch electrode layer on the base substrate and an orthographic projection of the second touch electrode layer on the base substrate.

15. The touch display panel according to claim 1, further comprising: a plurality of lens structures, wherein the plurality of lens structures are located on a side of the touch layer facing away from the base substrate, and an orthographic projection of each lens structure on the base substrate covers an orthographic projection of a corresponding anti-peeping pixel aperture on the base substrate.

16. The touch display panel according to claim 1, wherein the plurality of sharing sub-pixels are grouped into a plurality of sharing pixel units, each sharing pixel unit comprising at least two sharing sub-pixels; the plurality of anti-peeping sub-pixels are grouped into a plurality of anti-peeping pixel units, each anti-peeping pixel unit comprising at least two anti-peeping subpixels,
wherein the plurality of sharing pixel units are grouped into a plurality of rows of sharing pixel unit rows, the plurality of anti-peeping pixel units are grouped into a plurality of rows of anti-peeping pixel unit rows, and the sharing pixel unit rows and the anti-peeping pixel unit rows are alternately arranged.

17. A display device, comprising the touch display panel according to claim 1.

18. A method of manufacturing a touch display panel, comprising:
forming a plurality of sub-pixels on a base substrate, wherein the plurality of sub-pixels comprise a plurality of sharing sub-pixels and a plurality of anti-peeping sub-pixels, and each anti-peeping sub-pixel comprises at least two anti-peeping pixel apertures;
forming a first light-shielding layer on a side of the plurality of sub-pixels facing away from the base substrate, wherein the first light-shielding layer defines a plurality of first apertures, an orthographic projection of each first aperture on the base substrate at least partially overlaps with an orthographic projection of a corresponding anti-peeping pixel aperture on the base substrate, and at least part of an orthographic projection of the first light-shielding layer on the base substrate is located at a periphery of an orthographic projection of at least part of the anti-peeping pixel apertures on the base substrate; and
forming a touch layer on a side of the first light-shielding layer facing away from the base substrate, wherein the touch layer is reused as a second light-shielding layer, an orthographic projection of the second light-shielding layer on the base substrate defines a plurality of second apertures, each second aperture at least partially overlaps with an orthographic projection of a corresponding anti-peeping pixel aperture on the base substrate, and at least part of the orthographic projection of the second light-shielding layer on the base substrate is located at a periphery of the orthographic projection of at least part of the anti-peeping pixel apertures on the base substrate.

19. The touch display panel according to claim 2, wherein the touch layer comprises at least one touch electrode layer, and the touch electrode layer is reused as the second light-shielding layer.

20. The touch display panel according to claim 2, wherein the touch layer comprises a first touch electrode layer and a second touch electrode layer that are sequentially stacked along a direction away from the base substrate; the touch display panel comprises two stacked second light-shielding layers, the first touch electrode layer being reused as one second light-shielding layer, and the second touch electrode layer being reused as the other second light-shielding layer.
